(19) United States
(12) Patent Application Publication
(10) Pub. No.: US 2010/0055626 A1
(43) Pub. Date: Mar. 4, 2010

(54) METHOD FOR PATTERN FORMATION

(75) Inventors: Masayuki Endou, Osaka (JP); Masaru Sasago, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/613,165

(22) Filed: Nov. 5, 2009

Related U.S. Application Data
(63) Continuation of application No. PCT/JP2008/003521, filed on Nov. 28, 2008.

(30) Foreign Application Priority Data
Jan. 9, 2008 (JP) 2008-001860

(51) Int. Cl. G03F 7/20

(52) U.S. Cl. 430/326

(57) ABSTRACT

A resist film made of a chemically amplified positive resist is formed on a substrate. On the resist film, a light absorbing film containing a fluoropolymer which is alkali-soluble and has an aromatic ring is formed. Thereafter, first pattern exposure is performed by irradiating the resist film through the light absorbing film with first exposure light containing extreme ultraviolet light having passed through a first mask. Thereafter, second pattern exposure is performed by irradiating the resist film through the light absorbing film with exposure light having passed through a second mask. After the substrate is heated, the resist film is developed to remove the light absorbing film and form a resist pattern made of the resist film. An opening portion of the second mask is formed in a region corresponding to a non-opening portion of the first mask in which an opening portion is not formed.

### CROSS-REFERENCE TO RELATED APPLICATIONS

This is a continuation of PCT International Application PCT/JP2008/003521 filed on Nov. 28, 2008, which claims priority to Japanese Patent Application No. 2008-001860 filed on Jan. 9, 2008. The disclosures of these applications including the specifications, the drawings, and the claims are hereby incorporated by reference in their entirety.

### BACKGROUND

The present disclosure relates to pattern forming methods which are used in manufacturing processes of semiconductor devices or the like.

As the scales of semiconductor integrated circuits increase and the sizes of semiconductor devices decrease, there is a demand for acceleration of the development of lithography technology. At present, pattern formation is performed by optical lithography using, as exposure light, a mercury lamp, a KrF excimer laser, an ArF excimer laser or the like. The use of extreme ultraviolet light having a shorter wavelength is also being studied. Moreover, in addition to the reduction in the wavelength of an exposure light source, a technique called a double patterning method has been proposed so as to increase the degree of miniaturization (see, for example, NON-PATENT DOCUMENT 1). In the double patterning method, a desired mask pattern is formed by exposure using two separate masks, whereby pattern contrast can be improved. The resolution of lithography is defined by k1·λ/NA where k1 is a process constant, λ is the wavelength of exposure light, and NA is the numerical aperture of an exposure apparatus. According to the double patterning method, the improvement in the pattern contrast has the effect of significantly reducing the value of k1, and therefore, the resolution can be dramatically improved using the same exposure light.

In the double patterning method described in NON-PATENT DOCUMENT 1, a first pattern obtained by a first exposure and development process is transferred onto a hard mask by etching, and thereafter, a resist film is formed on the hard mask again, and a second pattern obtained by a second exposure and development process is transferred onto the hard mask by etching. Further, the first and second patterns transferred onto the hard mask are transferred onto a substrate by etching. Thus, the procedure is complicated.

In the simplest form of the double patterning method, the hard mask is not used, and after the resist film is formed, two separate exposure and development processes are performed to form a fine pattern.

A conventional pattern forming method which is a double patterning method which does not employ a hard mask will be described hereinafter with reference to FIGS. 5A to 5D and FIG. 6.

Initially, a chemically amplified positive resist material having the following composition is prepared.

| | | |
|---|---|---|
| Poly(vinyl phenol (50 mol %)-t-butyl acrylate (50 mol %)) | 2 | g |
| Triphenylsulfonium trifluoromethanesulfonic acid | 0.05 | g |
| (acid generating agent) | | |
| Triethanolamine (quencher) | 0.002 | g |
| Propylene glycol monomethyl ether acetate (solvent) | 20 | g |

Next, as shown in FIG. 5A, the chemically amplified resist material is applied onto a substrate 1 to form a resist film 2 having a thickness of 0.10 μm.

Next, as shown in FIG. 5B, the resist film 2 is irradiated with first exposure light 3 containing extreme ultraviolet light having an NA of 0.25 and a wavelength of 13.5 nm, which has passed through a first mask (not shown). This is a first pattern exposure step.

Next, as shown in FIG. 5C, the resist film 2 is irradiated with second exposure light 4 containing extreme ultraviolet light having an NA of 0.25 and a wavelength of 13.5 nm, which has passed through a second mask (not shown) having opening portions in regions corresponding to non-opening portions of the first mask. This is a second pattern exposure step.

Next, as shown in FIG. 5D, after the two pattern exposure processes, the resist film 2 is heated at a temperature of 105° C. for 60 seconds by a hot plate, and is then developed using an aqueous solution of tetramethylammonium hydroxide having a concentration of 2.38 wt %. As a result, as shown in FIG. 6, a resist pattern 2a made of unexposed portions of the resist film 2 is obtained.

### CITATION LIST

### Patent Documents

PATENT DOCUMENT 1: Japanese Laid-Open Patent Publication No. H06-148896

PATENT DOCUMENT 2: Japanese Laid-Open Patent Publication No. 2005-264131

### Non-Patent Documents

NON-PATENT DOCUMENT 1: M. Maenhoudt, J. Versluijs, H. Struyf, J. Van Olmen, M. Van Hove, “Double Patterning scheme for sub-0.25 k1 single damascene structures at NA=0.75, λ=193 nm”, Proc. SPIE, Vol. 5754, p. 1508 (2005)

### SUMMARY

However, the conventional double patterning method which does not employ a hard mask has a problem that a fine resist pattern cannot be satisfactorily formed.

In the conventional double patterning method, it may seem that the resultant resist pattern 2a has a high contrast pattern which is a combination of two separate patterns of the first and second masks. However, a pattern shape actually obtained is a defective pattern in which an upper portion of the resist pattern is rounded.

The present inventors have widely studied what is responsible for the defective resist pattern shape which is obtained by the double patterning method which does not employ a hard mask, to reach the following conclusion. Specifically, in the exposure step using the first mask and the exposure step using the second mask, light leaks into each unexposed portion of the resist film 2, and regions of the unexposed portions which are exposed by the leakage light are developed.

Thus, if a film to be treated is etched using the resist pattern 2a having a defective shape, the resultant film also has a defective pattern shape, and therefore, the productivity and yield of a semiconductor device manufacturing process are reduced, which is a problem.

In view of the aforementioned problem with the conventional technique, it is an object of the present disclosure to prevent the occurrence of a defective pattern due to double patterning methods, thereby obtaining a fine pattern having a good shape.

According to the result of the aforementioned study, the present inventors have found out that, by forming on the resist film a film containing a fluoropolymer which is alkali-soluble and has an aromatic ring, light which would otherwise leak into the unexposed portions when pattern exposure is performed using the first and second masks can be absorbed.

The present disclosure is based on the finding, and specifically, is achieved by the following method.

A first pattern forming method according to the present disclosure includes the steps of (a) forming on a substrate a resist film made of a chemically amplified positive resist, (b) forming on the resist film a light absorbing film containing a fluoropolymer which is alkali-soluble and has an aromatic ring, (c) performing first pattern exposure by selectively irradiating the resist film through the light absorbing film with exposure light containing extreme ultraviolet light having passed through a first mask, (d) after step (c), performing second pattern exposure by selectively irradiating the resist film through the light absorbing film with exposure light containing extreme ultraviolet light having passed through a second mask, and (e) after step (d), developing the resist film to remove the light absorbing film and form a resist pattern from the resist film. An opening portion of the second mask is formed in a region corresponding to a non-opening portion of the first mask in which an opening portion is not formed.

Also, a second pattern forming method according to the present disclosure includes the steps of (a) forming on a substrate a resist film made of a chemically amplified positive resist, (b) forming on the resist film a light absorbing film containing a fluoropolymer which is alkali-soluble and has an aromatic ring, (c) performing first pattern exposure by selectively irradiating the resist film through the light absorbing film with exposure light containing extreme ultraviolet light having passed through a first mask, (d) after step (c), performing second pattern exposure by selectively irradiating the resist film through the light absorbing film with exposure light containing extreme ultraviolet light having passed through a second mask, (e) after step (d), removing the light absorbing film, and (f) after step (e), developing the resist film to form a resist pattern from the resist film. An opening portion of the second mask is formed in a region corresponding to a non-opening portion of the first mask in which an opening portion is not formed.

According to the first or second pattern forming method, as fluorine atoms have the property of absorbing extreme ultraviolet light, the light absorbing film containing a fluoropolymer having an aromatic ring can absorb light which would otherwise leak into unexposed portions during exposure with extreme ultraviolet light having passed through the first mask and during exposure with extreme ultraviolet light having passed through the second mask. As a result, it is possible to prevent a resist pattern from being formed in a defective shape due to irradiation with multiple leakage light beams, which is a conventional problem.

Note that, when a light absorbing film which absorbs ultraviolet light is formed on a resist film, the light absorbing film absorbs exposure light which should be allowed into exposed portions of the resist film to some extent. However, the intensity of the exposure light is much higher than that of the leakage light, and therefore, the absorption is not such that a defective pattern is formed.

One of the features of the present disclosure is that the use of a fluoropolymer as a polymer included in the light absorbing film can increase the proportion of fluorine in the polymer. Conventionally, a fluorine-containing surfactant is added to an anti-interference film for exposure light so as to control the refractive index (see, for example, PATENT DOCUMENT 1). In contrast to this, the fluoropolymer having an aromatic ring of the present disclosure can significantly increase the proportion of fluorine in the polymer. Also, the effect of absorbing extreme ultraviolet light by fluorine can be enhanced as fluorine atoms are more uniformly distributed in the polymer. The fluorine content of the polymer included in the light absorbing film may be any value that allows absorption of leakage light, for example, about 1 wt % or more and 10 wt % or less.

Also, conventionally, when exposure is performed by immersion lithography, an alkali-soluble fluoropolymer containing an alicyclic group may be used as a protective film which is provided on a resist film and enhances hydrophobicity (see, for example, PATENT DOCUMENT 2).

In contrast to this, the light absorbing film employing a fluoropolymer having an aromatic ring according to the present disclosure has a higher proportion of carbon than that of a fluoropolymer containing an alicyclic group, and therefore, can improve absorption of extreme ultraviolet light to some extent. Therefore, the absorption characteristic with respect to extreme ultraviolet light can be controlled without depending only on fluorine.

Note that, in the first or second pattern forming method, as an example, poly(vinyl-2-fluorophenol), poly(vinyl-2,6-difluorophenol), or poly(vinyl-2,3,5,6-tetrafluorophenol) can be used as the fluoropolymer having an aromatic ring.

Also, more preferably, a polymer having an aromatic ring containing a hexafluoroisopropyl group can be used as the fluoropolymer having an aromatic ring so as to improve the alkali-solubility.

Here, as the fluoropolymer having an aromatic ring containing a hexafluoroisopropyl group, poly(vinylbenzene oxyhexafluoroisopropyl alcohol) or poly(vinylnaphthalene oxyhexafluoroisopropyl alcohol) can be used.

Note that, in the present disclosure, the light absorbing film containing a fluoropolymer which is alkali-soluble and has an aromatic ring can be used without being heated after the film has been formed. This is because the light absorbing film containing a fluoropolymer which is alkali-soluble and has an aromatic ring according to the present disclosure is provided only for the purpose of absorption of leakage light during exposure, and the resistance of the film is not required. In the case of a topcoat film (protective film) involved in conventional immersion lithography, heating is required to improve the density of the topcoat film itself so as to prevent the components of a resist film from being dissolved into a solution for immersion or to prevent the immersion solution from penetrating into the resist film. In the present disclosure, the light absorbing film does not require heating, and therefore, the process is easier.

Also, the light absorbing film containing a fluoropolymer which is alkali-soluble and has an aromatic ring according to the present disclosure may be removed at the same time during alkaline development as in the first pattern forming method, or alternatively, may be removed before development as in the second pattern forming method. In the case of the first pattern forming method, by removing the light absorbing film during development, the dissolution characteristic of the resist can be controlled. As a result, the dissolution characteristic of the resist is improved. In contrast to this, in the case of the second pattern forming method, the light absorbing film is removed before development, and therefore, the development process of the resist is performed in a typical manner. Note that, when the light absorbing film is removed before development, the light absorbing film may be removed using an alkaline solution, such as a diluted alkaline development solution.

Also, as the extreme ultraviolet light for exposure, for example, extreme ultraviolet light having a wavelength of 13.5 nm can be used. Note that the present disclosure is not limited to this wavelength.

According to the pattern forming method of the present disclosure, it is possible to prevent the occurrence of a defective pattern which would otherwise occur in double patterning methods which do not employ a hard mask, thereby obtaining a fine pattern having a good shape.

### BRIEF DESCRIPTION OF THE DRAWINGS

FIGS. 1A to 1D are cross-sectional views showing steps of a pattern forming method according to a first embodiment of the present disclosure.

FIGS. 2A and 2B are cross-sectional views showing steps of the pattern forming method of the first embodiment of the present disclosure.

FIGS. 3A to 3D are cross-sectional views showing steps of a pattern forming method according to a second embodiment of the present disclosure.

FIGS. 4A to 4C are cross-sectional views showing steps of the pattern forming method of the second embodiment of the present disclosure.

FIGS. 5A to 5D are cross-sectional views showing steps of a pattern forming method which is a conventional double patterning method which does not employ a hard mask.

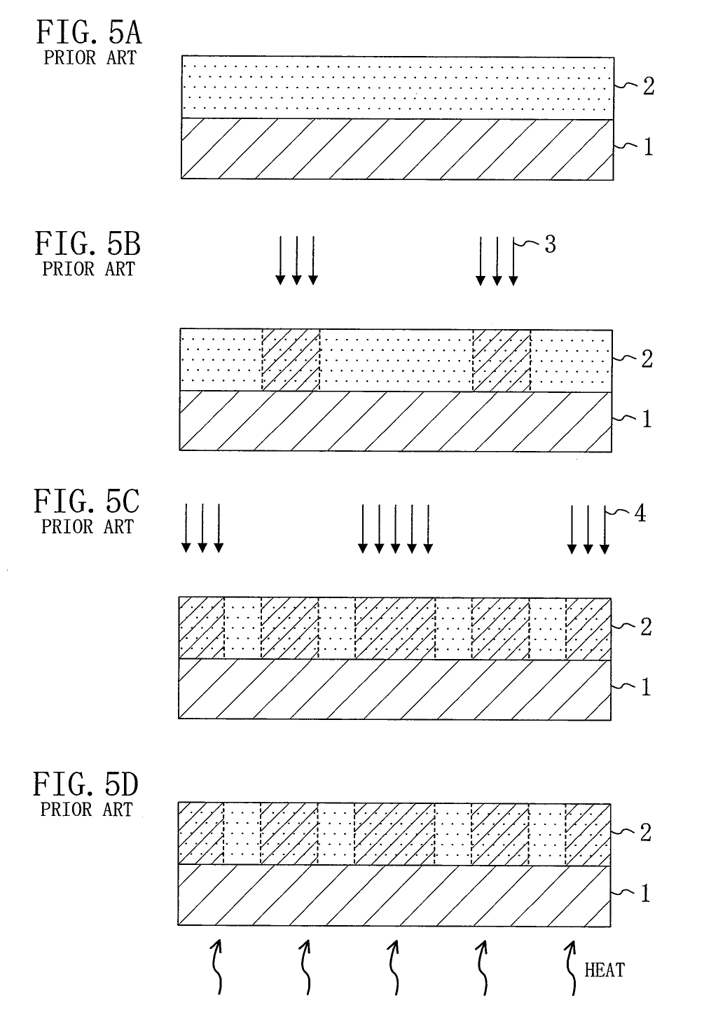

FIG. 6 is a cross-sectional view showing a step of the pattern forming method which is a conventional double patterning method which does not employ a hard mask.

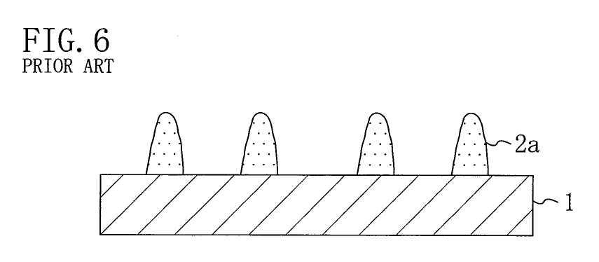

### DETAILED DESCRIPTION

### First Embodiment

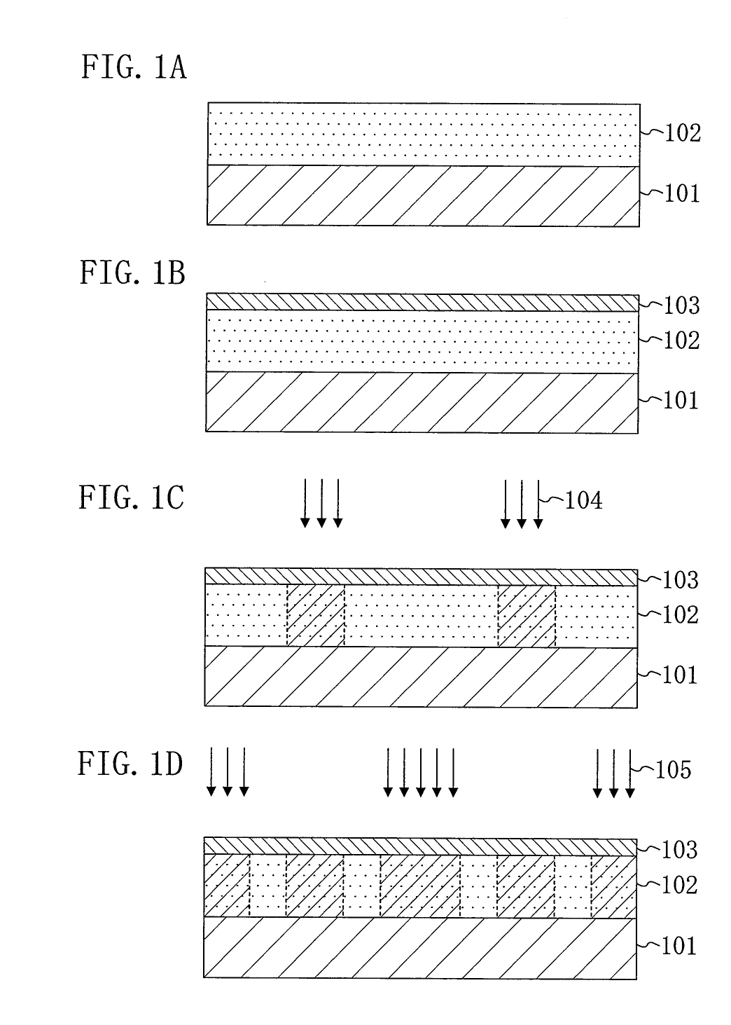

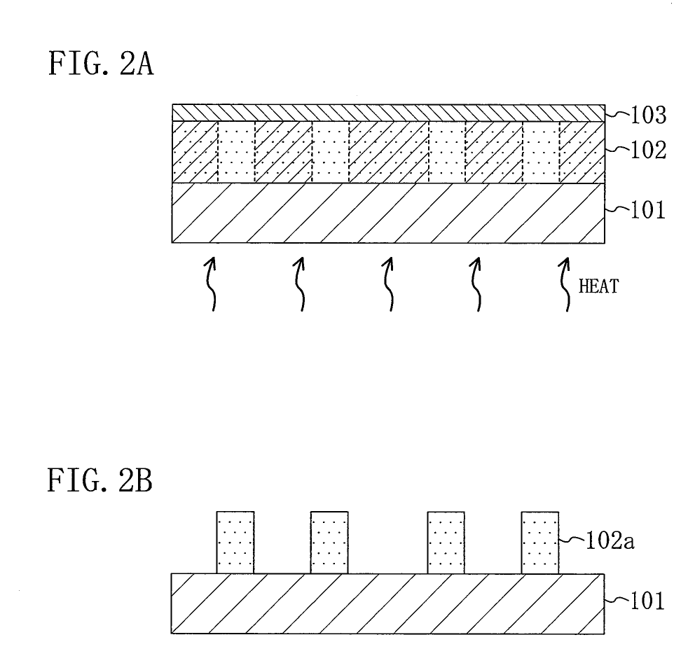

A pattern forming method employing a double patterning method according to a first embodiment of the present disclosure will be described with reference to FIGS. 1A to 1D and FIGS. 2A and 2B.

Initially, a chemically amplified positive resist material having the following composition is prepared.

| | | |
|---|---|---|
| Poly(vinyl phenol (50 mol %)-t-butyl acrylate (50 mol %)) | 2 | g |
| Triphenylsulfonium trifluoromethanesulfonic acid | 0.05 | g |
| (acid generating agent) | | |
| Triethanolamine (quencher) | 0.002 | g |
| Propylene glycol monomethyl ether acetate (solvent) | 20 | g |

Next, as shown in FIG. 1A, the chemically amplified resist material is applied onto a substrate 101 to form a resist film 102 having a thickness of 0.10 μm.

Next, as shown in FIG. 1B, a 60 nm-thick light absorbing film 103 made of a light absorbing film forming material containing a fluoropolymer which is alkali-soluble and has an aromatic ring is formed on the resist film 102 by, for example, a spin coating method. The light absorbing film forming material has the following composition.

| | |
|---|---|
| Poly(vinylbenzene oxyhexafluoroisopropyl alcohol) | 1 g |
| Sec-butyl alcohol | 20 g |

Next, as shown in FIG. 1C, the resist film 102 is irradiated through the light absorbing film 103 with first exposure light 104 containing extreme ultraviolet light having an NA of 0.25 and a wavelength of 13.5 nm, which has passed through a first mask (not shown). This is a first pattern exposure step.

Next, as shown in FIG. 1D, the resist film 102 is irradiated through the light absorbing film 103 with second exposure light 105 containing extreme ultraviolet light having an NA of 0.25 and a wavelength of 13.5 nm, which has passed through a second mask (not shown) having opening portions in regions corresponding to non-opening portions of the first mask. This is a second pattern exposure step.

Next, as shown in FIG. 2A, after the two pattern exposure processes, the resist film 102 is heated at a temperature of 105° C. for 60 seconds by a hot plate (post-exposure bake).

Next, as shown in FIG. 2B, the resist film 102 is developed using an aqueous solution of tetramethylammonium hydroxide having a concentration of 2.38 wt %. As a result, a resist pattern 102a made of unexposed portions of the resist film 102 is obtained. The resist pattern 102a has a high-contrast fine pattern which is a combination of two separate patterns of the first and second masks.

Thus, according to the first embodiment, in a double patterning method where extreme ultraviolet light is used as exposure light and a hard mask is not used, the light absorbing film 103 made of a fluoropolymer which is alkali-soluble and has an aromatic ring, such as poly(vinylbenzene oxyhexafluoroisopropyl alcohol), is formed on the resist film 102. Therefore, fluorine atoms contained in the light absorbing film 103 absorb light which would otherwise leak into each unexposed portion of the resist film 102 in the first pattern exposure step using the first mask of FIG. 1C and in the second pattern exposure step using the second mask of FIG. 1D. As a result, the resist pattern 102a has a pattern shape having high squareness, i.e., an upper portion thereof is not rounded.

### Second Embodiment

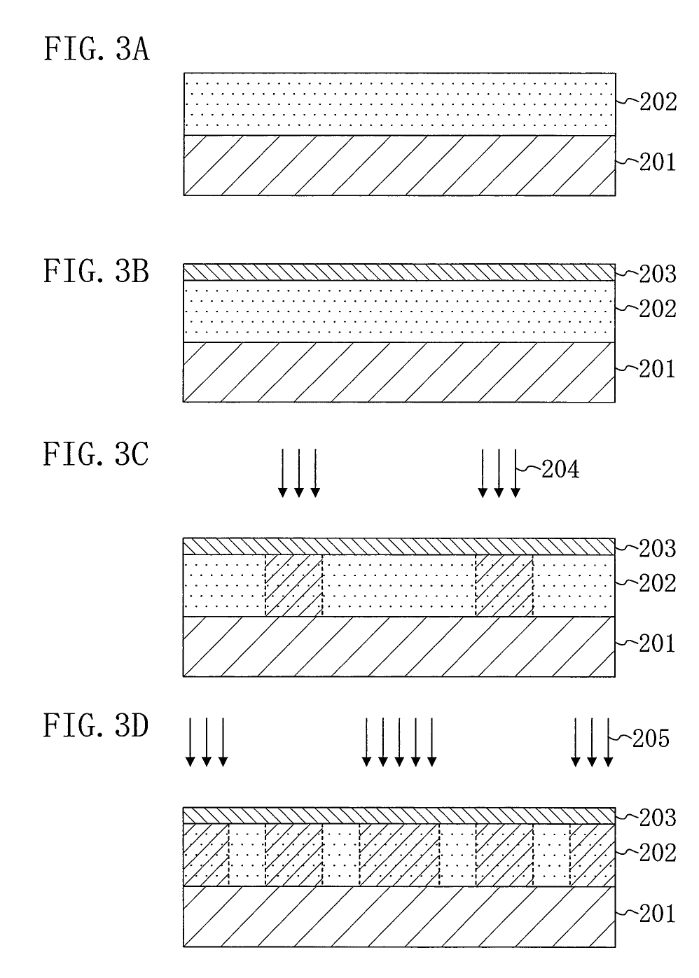

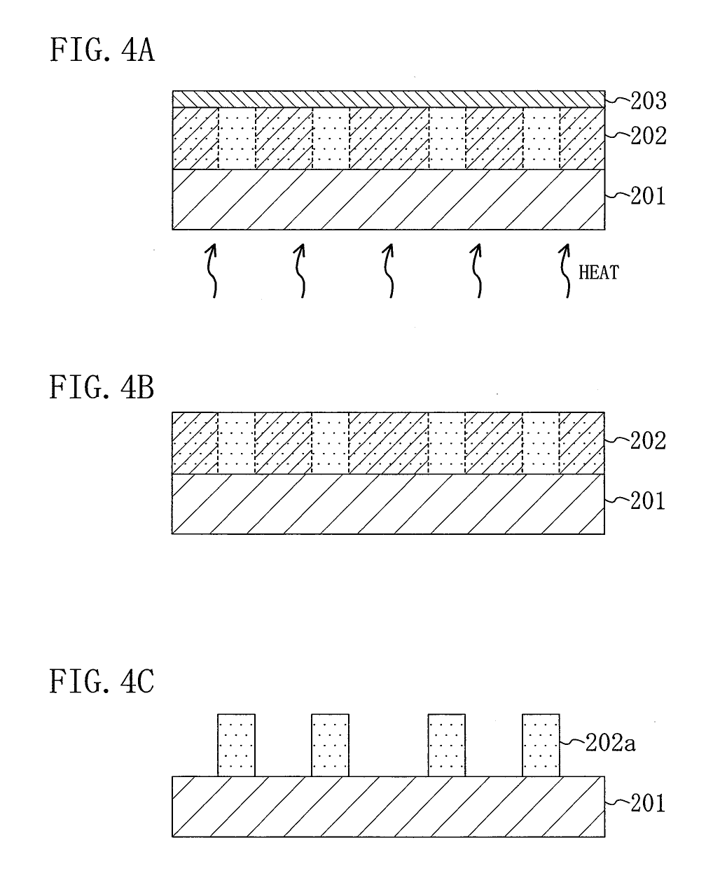

Hereinafter, a pattern forming method employing a double patterning method according to a second embodiment of the present disclosure will be described with reference to FIGS. 3A to 3D and FIGS. 4A to 4C.

Initially, a chemically amplified positive resist material having the following composition is prepared.

| | | |
|---|---|---|
| Poly(vinyl phenol (50 mol %)-t-butyl acrylate (50 mol %)) | 2 | g |
| Triphenylsulfonium trifluoromethanesulfonic acid | 0.05 | g |
| (acid generating agent) | | |
| Triethanolamine (quencher) | 0.002 | g |
| Propylene glycol monomethyl ether acetate (solvent) | 20 | g |

Next, as shown in FIG. 3A, the chemically amplified resist material is applied onto a substrate 201 to form a resist film 202 having a thickness of 0.10 μm.

Next, as shown in FIG. 3B, a 60 nm-thick light absorbing film 203 made of a light absorbing film forming material containing a fluoropolymer which is alkali-soluble and has an aromatic ring is formed on the resist film 202 by, for example, a spin coating method. The light absorbing film forming material has the following composition.

| | |
|---|---|
| Poly(vinyl-2-fluorophenol) | 1 g |
| Sec-butyl alcohol | 20 g |

Next, as shown in FIG. 3C, the resist film 202 is irradiated through the light absorbing film 203 with first exposure light 204 containing extreme ultraviolet light having an NA of 0.25 and a wavelength of 13.5 nm, which has passed through a first mask (not shown). This is a first pattern exposure step.

Next, as shown in FIG. 3D, the resist film 202 is irradiated through the light absorbing film 203 with second exposure light 205 containing extreme ultraviolet light having an NA of 0.25 and a wavelength of 13.5 nm, which has passed through a second mask (not mask. This is a second pattern exposure step.

Next, as shown in FIG. 4A, after the two pattern exposure processes, the resist film 202 is heated at a temperature of 105° C. for 60 seconds by a hot plate (post-exposure bake).

Next, as shown in FIG. 4B, the light absorbing film 203 is removed using an aqueous solution of tetramethylammonium hydroxide having a concentration of 0.05 wt %.

Next, as shown in FIG. 4C, the resist film 202 from which the light absorbing film 203 has been removed is developed using an aqueous solution of tetramethylammonium hydroxide having a concentration of 2.38 wt %. As a result, a resist pattern 202a made of unexposed portions of the resist film 202 is obtained. The resist pattern 202a has a high-contrast fine pattern which is a combination of two separate patterns of the first and second masks.

Thus, according to the second embodiment, in a double patterning method where extreme ultraviolet light is used as exposure light and a hard mask is not used, the light absorbing film 203 made of a fluoropolymer which is alkali-soluble and has an aromatic ring, such as poly(vinyl-2-fluorophenol), is formed on the resist film 202. Therefore, fluorine atoms contained in the light absorbing film 203 absorb light which would otherwise leak into each unexposed portion of the resist film 202 in the first pattern exposure step using the first mask of FIG. 3C and in the second pattern exposure step using the second mask of FIG. 3D. As a result, the resist pattern 202a has a satisfactory pattern shape having excellent squareness.

Although poly(vinylbenzene oxyhexafluoroisopropyl alcohol) or poly(vinyl-2-fluorophenol) is used as a fluoropolymer which is alkali-soluble and has an aromatic ring in each of the embodiments described above, the present disclosure is not limited to these. A similar satisfactory effect can be obtained when poly(vinylnaphthalene oxyhexafluoroisopropyl alcohol), poly(vinyl-2,6-difluorophenol) or poly(vinyl-2,3,5,6-tetrafluorophenol) is used.

Although the light absorbing film made of a fluoropolymer which is alkali-soluble and has an aromatic ring is assumed above to have a thickness of 60 nm, the present disclosure is not limited to this. Specifically, the lower limit of the thickness of the light absorbing film is about a thickness which allows the light absorbing film to sufficiently absorb leakage light during exposure, and the upper limit thereof is about a thickness that allows the light absorbing film not to prevent transmission of exposure light and to be easily removed. For example, the thickness of the light absorbing film is preferably about 20 nm or more and about 80 nm or less, more preferably about 30 nm or more and about 70 nm or less. Note that the present disclosure is not limited to these numeral ranges.

The pattern forming method of the present disclosure prevents the occurrence of a defective pattern which would otherwise occur in double patterning methods which do not employ a hard mask, thereby making it possible to obtain a fine pattern having a good shape, and is useful as, for example, a pattern forming method for use in a manufacturing process of semiconductor devices.

What is claimed is:

1. A pattern forming method comprising the steps of:
(a) forming on a substrate a resist film made of a chemically amplified positive resist;
(b) forming on the resist film a light absorbing film containing a fluoropolymer which is alkali-soluble and has an aromatic ring;
(c) performing first pattern exposure by selectively irradiating the resist film through the light absorbing film with exposure light containing extreme ultraviolet light having passed through a first mask;
(d) after step (c), performing second pattern exposure by selectively irradiating the resist film through the light absorbing film with exposure light containing extreme ultraviolet light having passed through a second mask; and
(e) after step (d), developing the resist film to remove the light absorbing film and form a resist pattern from the resist film,
wherein
an opening portion of the second mask is formed in a region corresponding to a non-opening portion of the first mask in which an opening portion is not formed.

2. The pattern forming method of claim 1, wherein
the fluoropolymer having the aromatic ring is poly(vinyl-2-fluorophenol), poly(vinyl-2,6-difluorophenol), or poly(vinyl-2,3,5,6-tetrafluorophenol).

3. The pattern forming method of claim 1, wherein
the fluoropolymer having the aromatic ring is a polymer having an aromatic ring containing a hexafluoroisopropyl group.

4. The pattern forming method of claim 3, wherein
the fluoropolymer having the aromatic ring containing the hexafluoroisopropyl group is poly(vinylbenzene oxyhexafluoroisopropyl alcohol) or poly(vinylnaphthalene oxyhexafluoroisopropyl alcohol).

5. The pattern forming method of claim 1, wherein
the exposure light containing the extreme ultraviolet light has a wavelength of 13.5 nm.

6. A pattern forming method comprising the steps of:
(a) forming on a substrate a resist film made of a chemically amplified positive resist;
(b) forming on the resist film a light absorbing film containing a fluoropolymer which is alkali-soluble and has an aromatic ring;
(c) performing first pattern exposure by selectively irradiating the resist film through the light absorbing film with exposure light containing extreme ultraviolet light having passed through a first mask;
(d) after step (c), performing second pattern exposure by selectively irradiating the resist film through the light absorbing film with exposure light containing extreme ultraviolet light having passed through a second mask;
(e) after step (d), removing the light absorbing film; and
(f) after step (e), developing the resist film to form a resist pattern from the resist film,
wherein
an opening portion of the second mask is formed in a region corresponding to a non-opening portion of the first mask in which an opening portion is not formed.

7. The pattern forming method of claim 6, wherein
the fluoropolymer having the aromatic ring is poly(vinyl-2-fluorophenol), poly(vinyl-2,6-difluorophenol), or poly(vinyl-2,3,5,6-tetrafluorophenol).

8. The pattern forming method of claim 6, wherein
the fluoropolymer having the aromatic ring is a polymer having an aromatic ring containing a hexafluoroisopropyl group.

9. The pattern forming method of claim 8, wherein
the fluoropolymer having the aromatic ring containing the hexafluoroisopropyl group is poly(vinylbenzene oxyhexafluoroisopropyl alcohol) or poly(vinylnaphthalene oxyhexafluoroisopropyl alcohol).

10. The pattern forming method of claim 6, wherein
the exposure light containing the extreme ultraviolet light has a wavelength of 13.5 nm.
